(19) United States
(12) Patent Application Publication
(10) Pub. No.: US 2020/0248667 A1
(43) Pub. Date: Aug. 6, 2020

(54) DATA CENTER WITH ENERGY-CONSERVING ABILITY

(71) Applicant: Shenzhen Fugui Precision Ind. Co., Ltd., Shenzhen (CN)

(72) Inventors: CHIH-HUNG CHANG, New Taipei (TW); CHAO-KE WEI, New Taipei (TW); TZE-CHERN MAO, New Taipei (TW); YEN-CHUN FU, New Taipei (TW)

(21) Appl. No.: 16/381,845

(22) Filed: Apr. 11, 2019

(30) Foreign Application Priority Data
Jan. 31, 2019 (CN) 201910095771.6

(51) Int. Cl. F03B 13/00; H05K 7/20; H05K 7/14

(52) U.S. Cl. CPC F03B 13/00; H05K 7/1492; H05K 7/20745

(57) ABSTRACT

A data center able to use the heat generated by its own operation for energy-saving purposes comprises at least one casing, a heat generating portion, an exhausting pipe, and a power generator. The heat generating portion received in the at least one casing generates heat in operating. The at least one casing defines an exhaust vent and an intake vent. The exhaust vent allows the at least one casing to communicate with the exhausting pipe. Cold air at the intake vent flows into the at least one casing and is heated by the heat generating portion to form a hot airflow. The exhausting pipe carries the hot airflow from the exhaust vent. The power generator is powered by the hot airflow in the exhausting pipe to produce electrical energy.

### FIELD

The subject matter herein generally relates to data center with energy conservation ability.

### BACKGROUND

The size of data center is increasing to accommodate big data. As a result, the data center generates a huge amount of heat. In related art, air cooling is generally used for cooling the data center. The heat generated by the data center is directly exhausted to the outdoors, and therefore is lost.

Thus, there is room for improvement in the art.

### BRIEF DESCRIPTION OF THE FIGURE

Implementations of the present disclosure will be described, by way of example only, with reference to the figure.

FIG. 1 is a diagram illustrating an embodiment of an energy conserving data center.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. The drawings are not necessarily to scale and the proportions of certain parts may be exaggerated to better illustrate details and features. The description is not to be considered as limiting the scope of the embodiments described herein.

The term “outside” refers to a region that is beyond the outermost confines of a physical object. The term “inside” indicates a region that is within a boundary formed by the object. The term “comprising” means “including, but not necessarily limited to”; it specifically indicates open-ended inclusion or membership in a so-described combination, group, series, and the like. The disclosure is illustrated by way of example and not by way of limitation in the figures of the accompanying drawings in which like references indicate similar elements. It should be noted that references to “an” or “one” embodiment in this disclosure are not necessarily to the same embodiment, and such references can mean “at least one.”

The present disclosure describes a data center with the ability to conserve energy.

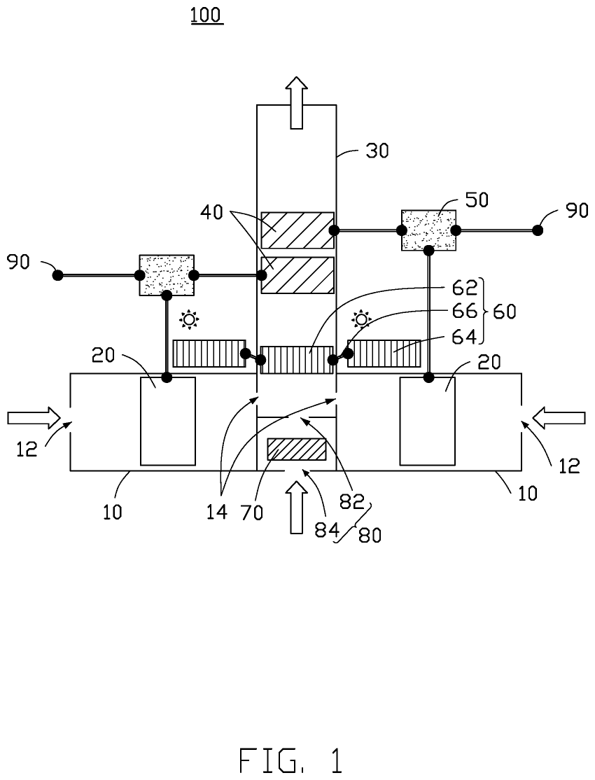

FIG. 1 shows a data center with an energy conservation ability 100. The data center 100 includes at least one casing 10, a heat generating portion 20, an exhausting pipe 30 perpendicularly provided to the at least one casing 10, and a generator 40. The at least one casing 10 is fixed on an end of the exhausting pipe 30. The power generator 40 is received in the exhausting pipe 30.

The at least one casing 10 defines an exhaust vent 14 at a junction of the at least one casing 10 and the exhausting pipe 30. The at least one casing 10 further defines an intake vent 12. The intake vent 12 is located at an end of the at least one casing 10 facing away from the exhaust vent 14. In one embodiment, the at least one casing 10 can be a container, a machine room, or a building unit, not being limited.

The heat generating portion 20 generates heat while the heat generating portion 20 being powered. The heat generating portion 20 is received in the at least one casing 10. In one embodiment, the heat generating portion 20 can be one or more electronic devices, such as a server, a storage medium, or a communication device, not being limited.

Cold air flows into the at least one casing 10 through the intake vent 12, and passes through the heat generating portion 20 for cooling the heat generating portion 20, thus a flow of hot air is formed, and flows to the exhaust vent 14. The hot airflow flows into the exhausting pipe 30 through the exhaust vent 14.

Air density of the hot airflow passing through the exhaust vent 14 is lower than air density of air outside the exhausting pipe 30, thus the hot airflow flows upwardly along the exhausting pipe 30 towards the outside. A force of the hot airflow exhausting from the exhausting pipe 30 drives the power generator 40 in the exhausting pipe 30 to generate electric energy. The greater the difference between the air density of the hot airflow in the exhausting pipe 30 and the air outside the exhausting pipe 30, the greater is the force that is generated. The greater the amount of the hot airflow exhausting from the exhausting pipe 30, the greater is the force of the hot airflow.

The power generator 40 is electrically connected to the heat generating portion 20, and powers the heat generating portion 20. In one embodiment, the power generator 40 is a wind-powered generator.

In one embodiment, the data center 100 includes two casings 10. The two casings 10 are provided oppositely to each other. The exhausting pipe 30 is perpendicularly located between the two casings 10. In other embodiments, the data center 100 can include more than two casings 10. The more than two casings 10 surround the exhausting pipe 30, and communicate with the exhausting pipe 30. The number of the casings 10 is adjustable based on an actual requirement.

Preferably, the data center 100 further includes a rectifier 50. The rectifier 50 electrically connects between the heat generating portion 20 and the power generator 40. The rectifier 50 further electrically connects with a public power grid 90.

The rectifier 50 can process the electrical energy generated by the power generator 40 and by the public power grid 90, and output a stable electrical energy to power the heat generating portion 20. The rectifier 50 further processes the electrical energy from the power generator 40 to the public power grid 90, thus excess electrical energy generated by the power generator 40 is transferred to the public power grid 90.

The rectifier 50 further determines whether the electrical energy generated by the power generator 40 meets a powering requirement, and further controls the heat generating portion 20 to adjust a manner of power use by the heat generating portion 20 based on the result.

While the electrical energy generated by the power generator 40 is sufficient for the powering requirement, the rectifier 50 controls the power generator 40 to directly power the heat generating portion 20. The excess electrical energy generated by the power generator 40 is further sold to the public power grid 90. While the electrical energy generated by the power generator 40 does not meet the powering requirement, the rectifier 50 allows and controls the public power grid 90 to power the heat generating portion 20. The heat generating portion 20 can thus be powered by the power generator 40 and the public power grid 90.

The data center 100 can further include a heat collecting module 60. The heat collecting module 60 can include a heat collector 62, a heat radiator 64, and a heat transferring portion 66.

The heat collector 62 connects with the heat radiator 64 through the heat transferring portion 66. The heat collector 62 is located outdoors, and collects solar energy. The heat transferring portion 66 includes a heating medium (not shown), and transfers the solar energy collected by the heat collector 62 to the heat radiator 64. The heat radiator 64 is located between the power generator 40 and the exhaust vent 14, and applies solar energy towards heating the hot airflow from the exhaust vent 14 into the base of the exhausting pipe 30. The force of the hot airflow flowing upwardly is thus increased, and the electrical energy output by the power generator 40 is also increased.

In one embodiment, the data center 100 can further include a heater 70 and an auxiliary heating portion 80. The auxiliary heating portion 80 is located at base of exhausting pipe 30 and at an end of the at least one casing 10 with the exhaust vent 14. A first opening is defined at a junction portion of the auxiliary heating portion 80 and the exhausting pipe 30. The auxiliary heating portion 80 further defines a second opening 84 at an end of the auxiliary heating portion 80 facing away from the first opening 82. The heater 70 in the auxiliary heating portion 80 is located between the first opening 82 and the second opening 84. The heater 70 heats a cold air at the second opening 84 to form a hot airflow. The hot airflow flows into the exhausting pipe 30 by passing through the first opening 82. The hot airflow increases the amount and the temperature of the hot airflow at the base of the exhausting pipe 30, thus the force of the hot airflow in the exhausting pipe 30 is increased.

In one embodiment, the heater 70 can generate heat by chemical activity, such as by burning combustibles. In other embodiments, the heater 70 can generate heat in a mechanical compression manner, such as a cylinder compression manner.

In one embodiment, the exhausting pipe 30 is a chimney.

Based on the structure of the data center 100, the hot airflow is exhausted from the exhausting pipe 30 to power the power generator 40. The power generator 40 generates the electrical energy driven by the hot airflow, and powers the heat generating portion 20. Thus, energy utilization is improved, reducing consumption and cost.

While various and preferred embodiments have been described the disclosure is not limited thereto. On the contrary, various modifications and similar arrangements (as would be apparent to those skilled in the art) are also intended to be covered. Therefore, the scope of the appended claims should be accorded the broadest interpretation so as to encompass all such modifications and similar arrangements.

What is claimed is:

1. A data center with an energy conservation ability comprising:
a heat generating portion configured to generate heat while being powered;
an exhausting pipe configured to exhaust air;
at least one casing configured to receive the heat generating portion; the at least one casing defines an exhaust vent and an intake vent located at an end facing away from the exhaust vent; the exhaust vent configured to communicate the at least one casing and the exhausting pipe; and
a power generator received in the exhausting pipe, and configured to provide electrical energy to the heat generating portion;
wherein cold air flows into the at least one casing through the intake vent, cools the heat generating portion to form a hot airflow; the hot airflow flows into the exhausting pipe through the exhaust vent, and drive the power generator to generate electrical energy.

2. The data center with an energy conservation ability of claim 1, wherein the data center with an energy conservation ability further comprises a rectifier; the rectifier electrically connects between the heat generating portion and the power generator; the rectifier further electrically connects with a public power grid; and the rectifier processes the electrical energy from the power generator and the public power grid, and outputs a stable electrical energy to power the heat generating portion.

3. The data center with an energy conservation ability of claim 2, wherein the rectifier further determines whether the electrical energy generated by the power generator meets a powering requirement, and adjusts a powering manner of the heat generating portion based on the result; while the electrical energy generated by the power generator is sufficient for the powering requirement, the rectifier controls the heat generating portion to be directly powered by the power generator; while the electrical energy generated by the power generator does not meet the power requirement, the rectifier controls the heat generating portion to be powered by the power generator and the public power grid.

4. The data center with an energy conservation ability of claim 3, wherein while the electrical energy generated by the power generator is more than the powering requirement of the heat generating portion, the rectifier controls an excess electrical energy generated by the power generator to be provided to the public power grid.

5. The data center with an energy conservation ability of claim 1, wherein the data center with an energy conservation ability further comprises a heat collecting module; the heat collecting module comprises a heat collector, a heat radiator, and a heat transferring portion located between the exhaust vent and the power generator; wherein the heat collector collects solar energy; the heat transferring portion transfers the solar energy to the heat radiator; and the heat radiator applies the solar energy towards heating the hot airflow from the exhaust vent into the exhausting pipe.

6. The data center with an energy conservation ability of claim 1, wherein the data center with an energy conservation ability further comprises an auxiliary heating portion; wherein the auxiliary heating portion adjacent to the exhaust vent of the at least one casing is located at the base of the exhausting pipe; a first opening is defined at a junction of the auxiliary heating portion and the exhausting pipe; and a second opening is defined at an end of the auxiliary heating portion facing away from the first opening.

7. The data center with an energy conservation ability of claim 6, wherein the data center with an energy conservation ability further comprises a heater; wherein the heater is located between the first opening and the second opening; and the heater heats the air flowed from the first opening to form a hot airflow.

8. The data center with an energy conservation ability of claim 7, wherein the heater generates heat by chemical activity.

9. The data center with an energy conservation ability of claim 7, wherein a manner of the heater generating heat is a mechanical compression manner.

10. The data center with an energy conservation ability of claim 1, wherein the exhausting pipe is a chimney.

11. The data center with an energy conservation ability of claim 1, wherein the data center with an energy conservation ability comprises two casings, the two casings are located opposite to each other; the exhausting pipe is perpendicularly connected between the two casings.

12. A data center with an energy conservation ability comprising:
at least one casing with an intake vent and an exhaust vent;
a heat generating portion received in the at least one casing, and configured to generate heat while being powered;
an exhausting pipe communicated with the at least one casing through the exhaust vent, and configured to exhaust the air; and
an auxiliary heating portion located at the base of the exhausting pipe, and adjacent to the exhaust vent;
wherein the cold air is heated by the powered generating portion to form a hot airflow, and the auxiliary heating portion further heats the hot airflow from the exhaust vent to the exhausting pipe, a force of the hot airflow in the exhausting pipe drives the power generator to generate electrical energy for powering the heat generating portion.

13. The data center with an energy conservation ability of claim 12, wherein the auxiliary heating portion further comprises a heater; a first opening is defined at a junction of the auxiliary heating portion and the exhausting pipe; a second opening is defined at an end of the auxiliary heating portion facing away from the first opening; wherein the heater is located between the first opening and the second opening; and the auxiliary heating portion further heats the cold air from the second opening to the first opening for increasing the hot airflow in the exhausting pipe.

14. The data center with an energy conservation ability of claim 12, wherein the data center with an energy conservation ability further comprises a heat collecting module; wherein the heat collecting module comprises a heat collector, a heat radiator, and a heat transferring portion located between the exhaust vent and the power generator; the heat collector collects solar energy; the heat transferring portion transfers the solar energy to the heat radiator; and the heat radiator applies the solar energy towards heating the hot airflow from the exhaust vent into the exhausting pipe.

15. The data center with an energy conservation ability of claim 12, wherein the data center with an energy conservation ability further comprises a rectifier; the rectifier electrically connects between the heat generating portion and the power generator; the rectifier further electrically connects with a public power grid; wherein the rectifier processes the electrical energy from the power generator and the public power grid, and outputs a stable electrical energy to power the heat generating portion.

16. The data center with an energy conservation ability of claim 15, wherein the rectifier further determines whether the electrical energy generated by the power generator meets a powering requirement, and adjusts a powering manner of the heat generating portion based on the result; while the electrical energy generated by the power generator is sufficient for the powering requirement, wherein the rectifier controls the heat generating portion to be directly powered by the power generator; while when the electrical energy generated by the power generator does not meet the power requirement, the rectifier controls the heat generating portion to be powered by the power generator and the public power grid.

17. The data center with an energy conservation ability of claim 15, wherein while the electrical energy generated by the power generator is sufficient for the powering requirement of the heat generating portion, the rectifier controls an excess electrical energy generated by the power generator to be provided to the public power grid.

18. The data center with an energy conservation ability of claim 12, wherein the data center with an energy conservation ability comprises two casings, the two casings are located opposite to each other; the exhausting pipe is perpendicularly connected between the two casings.

19. The data center with an energy conservation ability of claim 12, wherein the exhausting pipe is a chimney.
